(19) United States
(12) Patent Application Publication
(10) Pub. No.: US 2016/0276215 A1
(43) Pub. Date: Sep. 22, 2016

(54) Method for Manufacturing Semiconductor Device

(71) Applicant: UNITED MICROELECTRONICS CORPORATION, HSINCHU (TW)

(72) Inventors: PEI-TING LEE, Jiuru Township (TW); GUO-WEI CHEN, Tianzhong Township (TW); CHUN-LING LIN, Tainan City (TW); CHI-MAO HSU, Jiali Township (TW); CHING-WEI HSU, Changhua County (TW); HUEI-RU TSAI, Kaohsiung City (TW); JIA-RONG LI, Linluo Township (TW); SHANG NAN CHOU, Tainan City (TW); PO CHIH WU, Tainan City (TW)

(73) Assignee: UNITED MICROELECTRONICS CORPORATION, HSINCHU (TW)

(21) Appl. No.: 14/660,967

(22) Filed: Mar. 18, 2015

(51) Int. Cl. H01L 21/768

(52) U.S. Cl. CPC H01L 21/76843

(57) ABSTRACT

A method for manufacturing a semiconductor device is provided. The method comprises steps as follows. At least one trench is provided in a low-k dielectric layer on a substrate. The trench is filled with a copper (Cu) film. Pure cobalt (Co) is deposited on a surface of the Cu film by introducing a flow of a carrier gas carrying a Co-containing precursor and a reducing agent onto the surface of the Cu film. The flowrate of the flow is within a range from 5 to 19 sccm.

### FIELD OF THE INVENTION

The present invention generally relates to a method for manufacturing a semiconductor device and, more particularly, to a method for selectively depositing a pure cobalt (Co) cap layer on a copper (Cu) film inlaid in a low-k dielectric layer on a semiconductor device.

### BACKGROUND OF THE INVENTION

Damascene Cu has become a preferred material for creating conductive lines in high performance integrated circuits because of its relative low cost, processing properties and lower resistivity and higher resistance to electromigration (EM) compared to aluminum (Al).

However, Cu can readily diffuse into surrounding dielectric materials when subjected to high temperatures of subsequent fabrication processes. Diffusion of Cu into the surrounding insulating dielectric will lead to line-to-line leakages and eventual device failure. Therefore, it is necessary to fully enclose Cu lines with diffusion barriers.

Barrier and capping layers may be deposited to contain the copper. For example, tantalum, tantalum nitride, or Cu alloy with tin, aluminum, or magnesium has been used to provide a barrier layer or an adhesion promoter between Cu and other materials.

Moreover, to avoid time dependent dielectric breakdown (TDDB) phenomenon in low-k dielectrics in damascene copper interconnects, U.S. Pat. No. 8,278,216, for example, discloses a method for selectively depositing a metal nitride film on Cu lines.

In the present invention, a method for selectively depositing a pure Co cap layer on a Cu film inlaid in a low-k dielectric layer on a semiconductor device is provided to avoid time dependent dielectric breakdown (TDDB), to enhance the stability and adhesion of the Cu film and to improve the electromigration (EM) reliability of the Cu film.

### SUMMARY OF THE INVENTION

It is one object of the present invention to provide a method for selectively depositing a pure cobalt (Co) cap layer on a copper (Cu) film inlaid in a low-k dielectric layer on a semiconductor device.

In order to achieve the foregoing object, in one embodiment, the present invention provides a method for manufacturing a semiconductor device. The method includes the following steps. A method for manufacturing a semiconductor device is provided. The method comprises steps as follows. At least one trench is provided in a low-k dielectric layer on a substrate. The trench is filled with a Cu film. Pure Co is deposited on a surface of the Cu film by introducing a flow of a carrier gas carrying a Co-containing precursor and a reducing agent onto the surface of the Cu film. The flowrate of the flow is within a range from 5 to 19 sccm.

### BRIEF DESCRIPTION OF THE DRAWINGS

The present invention will become more readily apparent to those ordinarily skilled in the art after reviewing the following detailed description and accompanying drawings, in which:

FIG. 1A to FIG. 1C are cross-sectional views showing the steps for selectively depositing a pure cobalt (Co) cap layer on a copper (Cu) film inlaid in a low-k dielectric layer on a semiconductor device according to one embodiment of the present invention; and

FIG. 2A and FIG. 2B are cross-sectional views showing the mechanism for Co deposition.

### DETAILED DESCRIPTION OF PREFERRED EMBODIMENTS

The present invention will now be described more specifically with reference to the following embodiments. It is to be noted that the following descriptions of the embodiments of this invention are presented herein for purpose of illustration and description only. It is not intended to be exhaustive or to be limited to the precise form disclosed.

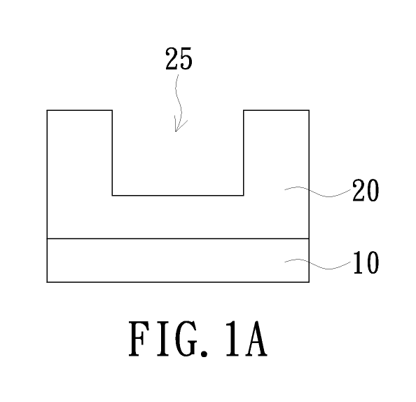

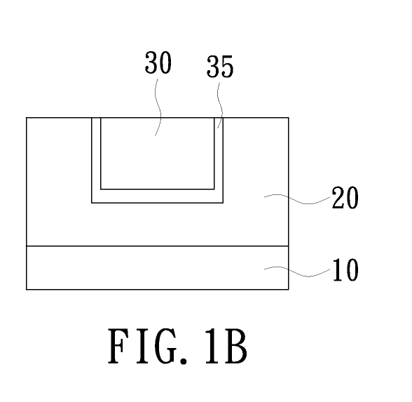

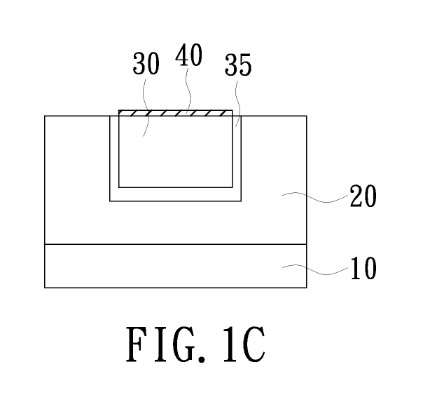

Please refer to FIG. 1A to FIG. 1C are cross-sectional views showing the steps for selectively depositing a pure cobalt (Co) cap layer on a copper (Cu) film inlaid in a low-k dielectric layer on a semiconductor device according to one embodiment of the present invention. In FIG. 1A, at least one trench 25 is provided in a low-k dielectric layer 20 on a substrate 10. In one embodiment, the substrate 10 may be, for example, a silicon substrate or a substrate with previously formed logic transistors thereon. The low-k dielectric layer 20 may include, for example, carbon containing oxide. The present invention is, however, not limited to the previous examples of the substrate 10 and the low-k dielectric layer 20.

The trench 25 is then filled with a Cu film 30 as shown in FIG. 1B. The Cu film 30 is formed by, for example, electro-chemical plating (ECP) followed by a chemical-mechanical polishing (CMP) process. Prior to the ECP process, a layer 35 as a barrier layer and a Cu seed layer is provided in the trench 25. The present invention is, however, not limited to the previous example of the formation of the Cu film 30.

In FIG. 1C, a pure Co cap layer 40 is selectively deposited on a surface of the Cu film 30. To deposit the pure Co cap layer 40 solely on the surface of the Cu film 30, a chemical vapor-phase deposition (CVD) process is used.

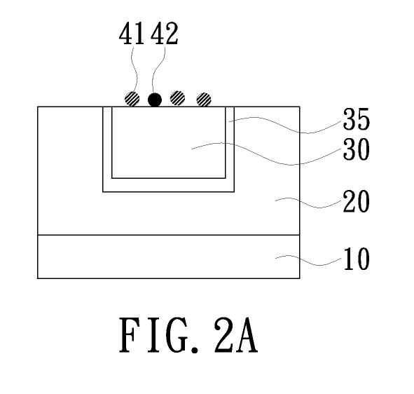

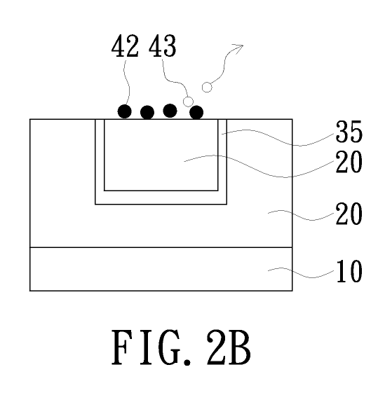

FIG. 2A and FIG. 2B are cross-sectional views showing the mechanism for Co deposition. First, a flow of a carrier gas carrying a Co-containing precursor and a reducing agent is introduced onto the surface of the Cu film 30. In one embodiment, the carrier gas includes Ar, the Co-containing precursor includes Co(C₅H₅)₂ or Co(C₅H₅)(CO)ₓ (x=1˜2), and the reducing agent includes hydrogen, nitrogen, ammonia (NH₃) or combinations thereof. The present invention is, however, not limited to the previous examples of the carrier gas, the Co-containing precursor and the reducing agent.

In one embodiment, as a flow of Ar carrying, for example, Co(C₅H₅)(CO)₂ and H₂ is introduced onto the surface of the Cu film 30, the Co(C₅H₅)(CO)₂ reacts with H₂ to produce Co(C₅H₅) 41, Co particles 42 and byproducts (not shown), as shown in FIG. 2A, when the substrate is heated up to, for example, 310° C. In one embodiment, the flowrate of the flow is within a range from 5 to 19 sccm. The present invention is, however, not limited to the previous examples of the flowrate.

It is preferable that the CVD process is followed by a plasma treatment performed on the surface of the Cu film to further deposit pure Co on the surface of the Cu film. In one embodiment, the plasma treatment is performed using plasma of hydrogen, nitrogen, ammonia (NH₃) or combinations thereof. The present invention is, however, not limited to the previous example of how the plasma treatment is implemented.

In one embodiment, the plasma treatment enables the Co(C₅H₅) 41 in FIG. 2A to further reduce to more Co particles 42 and gaseous byproducts 43, as shown in FIG. 2B.

In the present invention, the CVD process and the plasma treatment can be repeated as multiple cycles. For example, the method for selectively depositing pure Co on a Cu film inlaid in a low-k dielectric layer on a semiconductor device may start with the CVD process as shown in FIG. 2A and end at the plasma treatment as shown in FIG. 2B to complete a cycle. Alternatively, the method may also end at a repeated CVD process after a plurality of cycles. The present invention is, however, not limited to the previous number of cycles. Also, the present invention is not limited to whether the method ends at the CVD process or the plasma treatment.

It should be noted that the method of the present invention results in formation of a pure Co cap layer on the Cu film without significant formation on the surrounding dielectric material, which is attributed to the low carrier gas flow that leads to difficulty in depositing Co on the surrounding dielectric material. In other words, lower carrier gas flow results in higher selectivity when the selectivity is defined as (Co thickness on Cu)/(Co thickness on dielectric). More particularly, with the flow rate of the carrier gas within a range from 5 to 19 sccm, the selectivity reaches 75. Preferably, the selectivity reaches 150 with the flow rate within a range from 8 to 15 sccm. Preferably, the selectivity reaches 180 when the flow rate is 10 sccm.

The main feature of the present invention is that, by employing a deposition recipe of Co with a high selectivity between the interfaces with Cu and the interface with low-k dielectric, the method results in formation of a pure Co cap layer on the Cu film without significant formation on the surrounding dielectric material. With the realization of the present invention, a method for selectively depositing a pure Co cap layer on a Cu film inlaid in a low-k dielectric layer on a semiconductor device is provided to avoid time dependent dielectric breakdown (TDDB), to enhance the stability and adhesion of the Cu film and to improve the electromigration (EM) reliability of the Cu film.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for manufacturing a semiconductor device, comprising steps of:
providing at least one trench in a low-k dielectric layer on a substrate, said trench being filled with a copper (Cu) film; and
depositing pure Co on a surface of said Cu film by introducing a flow of a carrier gas carrying a Co-containing precursor and a reducing agent onto said surface of said Cu film;
wherein the flowrate of said flow is within a range from 5 to 19 sccm.

2. The method of claim 1, wherein said Co-containing precursor comprises Co(C₅H₅)₂ or Co(C₅H₅)(CO)_{x (x=1˜2)}.

3. The method of claim 1, wherein said reducing agent comprises hydrogen, nitrogen, ammonia (NH₃) or combinations thereof.

4. The method of claim 1, wherein said carrier gas comprises Ar.

5. The method of claim 1, further comprising a step of:
performing a plasma treatment on said surface of said Cu film to further deposit pure Co on said surface of said Cu film.

6. The method of claim 5, wherein said Co-containing precursor comprises Co(C₅H₅)₂ or Co(C₅H₅)(CO)_{x (x=1˜2)}.

7. The method of claim 5, wherein said reducing agent comprises hydrogen, nitrogen, ammonia (NH₃) or combinations thereof.

8. The method of claim 5, wherein said carrier gas comprises Ar.

9. The method of claim 5, wherein said plasma treatment is performed using plasma of hydrogen, nitrogen, ammonia (NH₃) or combinations thereof.

10. The method of claim 5, further comprising a step of:
further depositing pure Co on said surface of said Cu film by introducing said flow of said carrier gas carrying said Co-containing precursor and said reducing agent onto said surface of said Cu film again.

11. The method of claim 10, wherein said Co-containing precursor comprises Co(C₅H₅)₂ or Co(C₅H₅)(CO)_{x (x=1˜2)}.

12. The method of claim 10, wherein said reducing agent comprises hydrogen, nitrogen, ammonia (NH₃) or combinations thereof.

13. The method of claim 10, wherein said carrier gas comprises Ar.

14. The method of claim 10, wherein said plasma treatment is performed using plasma of hydrogen, nitrogen, ammonia (NH₃) or combinations thereof.

15. The method of claim 5, further comprising repeating, at least one time, steps of:
further depositing pure Co on said surface of said Cu film by introducing said flow of said carrier gas carrying said Co-containing precursor and said reducing agent onto said surface of said Cu film again; and
performing said plasma treatment on said surface of said Cu film to further deposit pure Co on said surface of said Cu film.

16. The method of claim 15, wherein said Co-containing precursor comprises Co(C₅H₅)₂ or Co(C₅H₅)(CO)_{x (x=1˜2)}.

17. The method of claim 15, wherein said reducing agent comprises hydrogen, nitrogen, ammonia (NH₃) or combinations thereof.

18. The method of claim 15, wherein said carrier gas comprises Ar.

19. The method of claim 15, wherein said plasma treatment is performed using plasma of hydrogen, nitrogen, ammonia (NH₃) or combinations thereof.

20. The method of claim 15, further comprising a step of:
further depositing pure Co on said surface of said Cu film by introducing said flow of said carrier gas carrying said Co-containing precursor and said reducing agent onto said surface of said Cu film again.
